(19) United States
(12) Patent Application Publication
(10) Pub. No.: US 2026/0317883 A1
(43) Pub. Date: Oct. 15, 2026

(54) DEPOSITION MASK, METHOD FOR MANUFACTURING THE DEPOSITION MASK, AND ELECTRONIC DEVICE

(71) Applicant: SAMSUNG DISPLAY CO., LTD., YONGIN-SI (KR)

(72) Inventors: Ji Hye HAN, YONGIN-SI (KR); Sung Woon KIM, YONGIN-SI (KR)

(21) Appl. No.: 19/380,208

(22) Filed: Nov. 5, 2025

(30) Foreign Application Priority Data
Apr. 11, 2025 (KR) 10-2025-0047390

(51) Int. Cl. C23C 14/04; H10K 59/12; H10K 71/16

(52) U.S. Cl. CPC C23C 14/042; H10K 59/1201; H10K 71/166

(57) ABSTRACT

A deposition mask includes first openings penetrating a first surface and a second opening penetrating a second surface and overlapping the first openings, each of the first openings includes a first opening volume and a second opening volume between the first opening volume and the second opening, and a first inclination angle of a side surface of the first opening volume is different from a second inclination angle of a side surface of the second opening volume.

### CROSS-REFERENCE TO RELATED APPLICATION

This application claims priority under 35 U.S.C. § 119 to Korean Patent Application No. 10-2025-0047390, filed in the Korean Intellectual Property Office on April 11, 2025, the entire disclosure of which is incorporated by reference herein.

### FIELD

The present disclosure generally relates to deposition masks, methods for manufacturing deposition masks, and electronic devices manufactured therewith; and more particularly relates to a deposition mask suitable for manufacturing information displays such as an electronic display device.

### INTRODUCTION

With the growing interest in information displays in recent years, research and development for display devices continues to take place.

### SUMMARY

Embodiments of the present disclosure may optimize the reliability of a deposition process and/or minimize the loss of deposition material.

Embodiments of the present disclosure are not necessarily limited to those mentioned above or described below, and various alternate embodiments may be contemplated by those of ordinary skill in the pertinent art based on the following description.

A deposition mask according to an embodiment includes first openings penetrating a first surface; and a second opening penetrating a second surface and overlapping the first openings, wherein each of the first openings includes a first opening volume and a second opening volume contiguous with the first opening volume and disposed between the first opening volume and the second opening, wherein a first inclination angle of a side surface of the first opening volume is different from a second inclination angle of a side surface of the second opening volume.

The deposition mask may include a base substrate; and an inorganic layer including a first portion on a first surface of the base substrate and a second portion on a second surface of the base substrate.

The first openings may penetrate the first portion of the inorganic layer.

The second opening may penetrate the base substrate and the second portion of the inorganic layer.

The inorganic layer may include a first inorganic layer on the base substrate and a second inorganic layer on the first inorganic layer.

The first inclination angle may be greater than the second inclination angle.

A horizontal width of the first opening volume may increase in a vertical direction.

A horizontal width of the first opening volume may be constant.

A horizontal width of the second opening volume may decrease in a vertical direction.

A method for manufacturing a deposition mask according to an embodiment includes: forming a pattern layer on a first surface of a base substrate; forming an inorganic layer on the pattern layer; forming first opening volumes, each having a side surface with a first inclination angle, by etching the inorganic layer on the pattern layer; forming second opening volumes, each contiguous with a respective first opening volume and having a side surface with a second inclination angle, by etching the pattern layer; and forming a second opening by etching the inorganic layer and the base substrate, wherein the first inclination angle is different from the second inclination angle.

A horizontal width of the pattern layer may decrease in a vertical direction.

The method for manufacturing a deposition mask may further include polishing an upper surface of the inorganic layer.

The first opening volumes may expose an upper surface of the pattern layer.

The pattern layer may be etched through the first opening volumes.

The second opening volumes may expose the first surface of the base substrate.

The inorganic layer may include a first portion formed on the first surface of the base substrate and a second portion formed on the second surface of the base substrate.

The first opening volumes may be formed by etching the first portion of the inorganic layer.

The second opening may be formed by etching the second portion of the inorganic layer and the base substrate.

The forming the inorganic layer may include forming a first inorganic layer on the pattern layer; and forming a second inorganic layer on the first inorganic layer.

An electronic device according to an embodiment is manufactured using a deposition mask including: first openings penetrating a first surface; and a second opening penetrating a second surface and overlapping the first openings, wherein each of the first openings includes a first opening volume and a second opening volume contiguous with the first opening volume and disposed between the first opening volume and the second opening, wherein a first inclination angle of a side surface of the first opening volume is different from a second inclination angle of a side surface of the second opening volume.

Illustrative details of these and other embodiments may be included in the detailed description that follows and the accompanying drawings.

According to an embodiment, a shadow effect may be optimized by partially forming the opening volume of the deposition mask in a substantially tapered shape, where the deposition thickness and the deposition area may be easily controlled and the loss of deposition material may be minimized.

Embodiments of the present disclosure are not necessarily limited by the above examples, and particularly illustrative embodiments are shown in the drawings and further described below.

### BRIEF DESCRIPTION OF THE DRAWINGS

FIG. 1 is a partial schematic side view diagram of a deposition device according to an embodiment.

FIG. 2 is a side view diagram of a deposition mask according to an embodiment.

FIG. 3 is an enlarged side view diagram of a first opening of the deposition mask of FIG. 2 according to an embodiment.

FIG. 4 is an enlarged side view diagram of a first opening of a deposition mask according to an embodiment.

FIG. 5 is a block diagram of a display device according to an embodiment.

FIG. 6 is a circuit diagram of any one of the sub-pixels of FIG. 5 according to an embodiment.

FIG. 7 is a plan view diagram of a display panel of FIG. 5 according to an embodiment.

FIG. 8 is an exploded perspective view diagram of a portion of the display panel of FIG. 7 according to an embodiment.

FIG. 9 is a block diagram of an electronic device according to an embodiment.

FIG. 10 is a schematic diagram of multiple configurations of the electronic device of FIG. 9 according to an embodiment.

FIGS. 11 to 17 are cross-sectional view diagrams of sequential process steps in a method for manufacturing a deposition mask according to an embodiment.

### DETAILED DESCRIPTION

Hereinafter, illustrative embodiments of the present disclosure may be described in greater detail with reference to the accompanying drawings. It should be noted that in the following description, only the parts necessary to understand the operation according to the present disclosure may be described, and descriptions of other parts may be omitted so as not to obscure the gist of the present disclosure. The present disclosure is not necessarily limited to the embodiments described herein, and may be embodied in other forms. However, the embodiments described herein are provided to explain the technical ideas of the present disclosure to a person skilled in the art to which the present disclosure pertains.

Throughout the specification, when a part is “connected” to another part, this may include not only an embodiment where the part is “directly connected” but also an embodiment where it is “indirectly connected” with another element interposed therebetween. The terminology used herein is for the purpose of describing particular embodiments and is not necessarily intended to limit the invention. Throughout the specification, when it is said that a part may “include” a component, this may mean that other components may be further included, rather than excluding other components, unless otherwise specified. For example, “at least one selected from the group consisting of X, Y, and Z”, can be interpreted as X, Y, Z, or any combination of two or more of X, Y, or Z, such as XYZ, XY, YZ, or ZX. Moreover, “at least one of X, Y, or Z” can be interpreted as X, Y, Z, any combination of two or more of X, Y, or Z, such as XYZ, XY, YZ, or ZX, with duplications permitted such as XX, YYY, ZZZZ, or the like. Here, “and/or” may include all combinations of one or more of the corresponding configurations.

Terms such as first, second, and the like may be used to describe and/or differentiate various components, but these components are not necessarily limited to these terms. For example, these terms may be used to distinguish one component from another. Accordingly, a first component may refer to a second component without limitation.

Spatially relative terms such as “below”, “above”, and the like may be used for purposes of description, thereby describing a relationship of one element or feature to another element (s) or feature (s), as shown in the figures. Spatially relative terms are intended to include different directions in use, operation, and/or manufacture, in addition to the directions depicted in the figures. For example, if the device shown in the figure is flipped over, elements depicted as being “below” other elements or features may be positioned in a direction “above” the other elements or features. Thus, in an embodiment, the term “below” may include both directions of above and below. In addition, the device may be directed in another direction (e.g., rotated 90 degrees or in some other direction), and thus, the spatially relative terms used herein may be interpreted accordingly.

Various embodiments may be described with reference to the figures schematizing idealized embodiments for explanatory purposes. Accordingly, it will be appreciated that the shapes may vary depending on, for example, tolerances and/or manufacturing techniques. While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

A deposition mask may include first openings penetrating a first surface, and a second opening penetrating a second surface and at least partially overlapping the first openings. Each of the first openings may include a first opening volume and a second opening volume contiguous with the first opening volume. Each second opening volume may be disposed between the respective first opening volume and the second opening.

Moreover, a first inclination angle of a side surface of the first opening volume may be different from a second inclination angle of a side surface of the second opening volume According to an embodiment of the present disclosure, a shadow effect may be optimized by using a deposition mask having openings with a partially tapered, hour-glass, or like-shaped boundary surface.

In an embodiment, a first inclination angle of a side surface of a first opening volume is different from a second inclination angle of a side surface of a second opening volume. Thus, for example, the deposition thickness and the deposition area may be readily controlled and/or the loss of deposition material may be minimized.

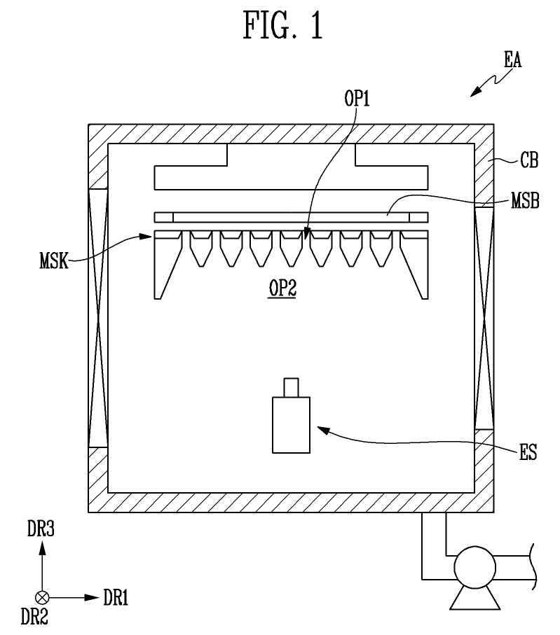

FIG. 1 illustrates an embodiment of a deposition device, indicated generally by the reference indicator EA.

As shown in FIG. 1, the deposition device EA may include a chamber boundary CB, a deposition source ES, and a deposition mask MSK.

The chamber boundary CB may surround or define an interior space or chamber. The interior space or chamber may be a workspace prepared for a deposition process. An object that is a deposition target may be placed or housed inside the interior space or chamber. For example, a main substrate MSB that is a deposition target may be placed inside the interior space or chamber defined by the chamber boundary CB.

The deposition source ES may be disposed within the chamber boundary CB. The deposition source ES may house a deposition material and supply the deposition material to the interior space or chamber. The deposition material may include a material that forms a specific pattern (e.g., a light-emitting layer) on the main substrate MSB. The deposition source ES may apply energy such as thermal energy, light energy, and/or vibrational energy to the deposition material to vaporize or sublimate the deposition material. For example, the deposition source ES may include a heater, and may heat the deposition material inside the deposition source ES through operation of the heater, thereby melting or sublimating the deposition material. The deposition source ES may be replaceable. For example, the deposition source ES may be replaced with a different deposition source when the deposition material housed therein is exhausted and/or when a different source or material is desired.

A deposition mask MSK may be placed between the main substrate MSB and the deposition source ES. The deposition mask MSK may be aligned to face the deposition target. The deposition mask MSK may block the deposition material in some blocked areas and not block the deposition material in other unblocked areas. Accordingly, the deposition material may be selectively deposed on specific unblocked areas of the deposition target. First openings OP1 may be areas provided by the other unblocked areas where the deposition material is not blocked. The deposition mask MSK may include a second opening OP2 that overlaps the first openings OP1. The first openings OP1 and the second opening OP2 may overlap in a third direction DR3. The deposition material may be provided to the deposition target (or the main substrate MSB) through the first opening OP1 and the second opening OP2.

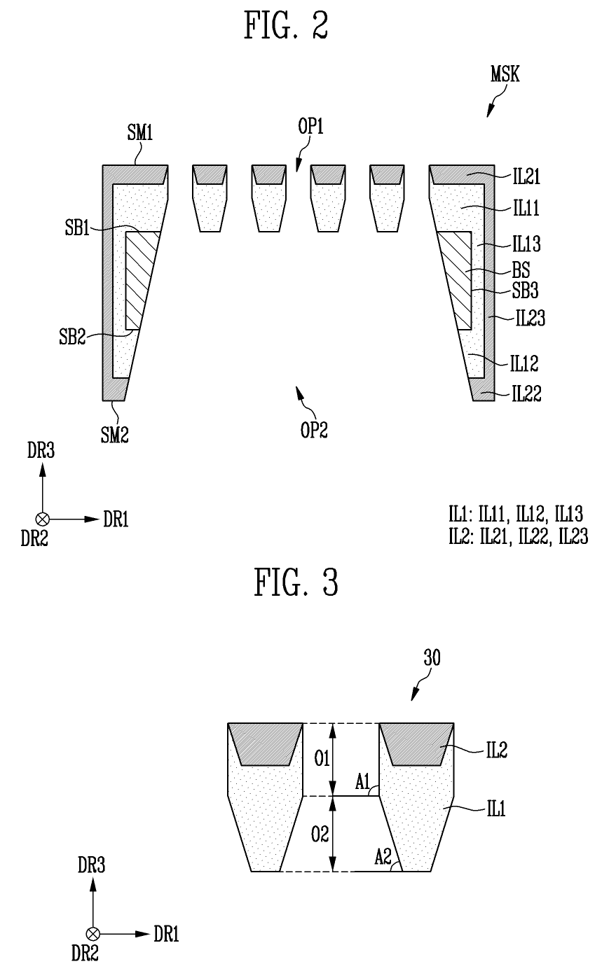

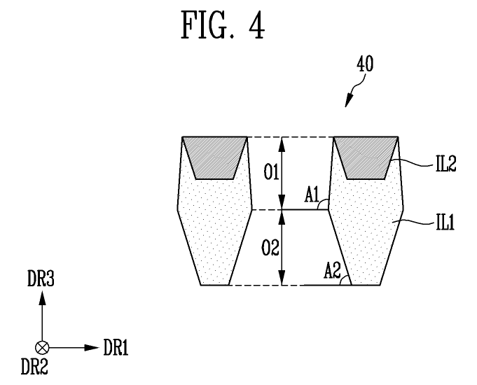

FIG. 2 illustrates an embodiment of a deposition mask, indicated generally by the reference indicator MSK. FIG. 3 illustrates an embodiment of a first opening of the deposition mask of FIG. 2, indicated generally by the reference numeral 30. FIG. 4 illustrates an embodiment of a first opening of a deposition mask according to an embodiment, indicated generally by the reference numeral 40.

Refer to FIGS. 2 to 4, the deposition mask MSK may include a base substrate BS and an inorganic layer having inorganic sub-layers IL1 and IL2.

The base substrate BS may include silicon, but is not necessarily limited thereto. On the base substrate BS, a first inorganic layer IL1 may be placed.

The first inorganic layer IL1 may be placed on a front or first surface SB1, a rear or second surface SB2, and a side or third surface SB3 of the base substrate BS. For example, the first inorganic layer IL1 may include a first section IL11 placed on the first surface SB1 of the base substrate BS, a second section IL12 placed on the second surface SB2 of the base substrate BS and a third section IL13 placed on the third surface SB3 of the base substrate BS. The first section IL11 of the first inorganic layer IL1 may be placed directly on the first surface SB1 of the base substrate BS. The second portion IL12 of the first inorganic layer IL1 may be placed directly on the second surface SB2 of the base substrate BS. The third portion IL13 of the first inorganic layer IL1 may be placed directly on the third surface SB3 of the base substrate BS. In an embodiment, the first inorganic layer IL1 may include silicon nitride (SiNx), but is not necessarily limited thereto.

A second inorganic layer IL2 may be placed on the first inorganic layer IL1.

The second inorganic layer IL2 may be placed on the first surface SB1, the second surface SB2, and the third surface SB3 of the base substrate BS. For example, the second inorganic layer IL2 may include a first section IL21 placed on the first portion IL11 of the first inorganic layer IL1, a second portion IL22 placed on the second portion IL12 of the first inorganic layer IL1, and a third portion IL23 placed on the third portion IL13 of the first inorganic layer IL1. The first portion IL21 of the second inorganic layer IL2 may be placed directly on the first section IL11 of the first inorganic layer IL1. The second section IL22 of the second inorganic layer IL2 may be placed directly on the second section IL12 of the first inorganic layer IL1. The third section IL23 of the second inorganic layer IL2 may be placed directly on the third section IL13 of the first inorganic layer IL1. In an embodiment, the second inorganic layer IL2 may include silicon oxide (SiOx), but is not necessarily limited thereto.

The deposition mask MSK may include first openings OP1 and a second opening OP2. The first openings OP1 may penetrate a front or first surface SM1 of the deposition mask MSK. The first openings OP1 may penetrate the first section IL11 of the first inorganic layer IL1 and the first section IL21 of the second inorganic layer IL2 in the third direction DR3. Accordingly, the deposition material may be provided to the main substrate MSB through the first openings OP1.

The first openings OP1 may each include a first opening volume O1 and a second opening volume O2. The first opening volume O1 and the second opening volume O2 may be arranged in the third direction DR3. The second opening volume O2 may be placed between the first opening volume O1 and the second opening OP2.

In an embodiment, a first inclination angle A1 of a side surface of the first opening volume O1 and a second inclination angle A2 of a side surface of the second opening volume O2 may be different from each other. The second inclination angle A2 of the side surface of the second opening volume O2 may be smaller than the first inclination angle A1 of the side surface of the first opening volume O1. For example, the first inclination angle A1 of the side surface of the first opening volume O1 may be greater than or substantially equal to 90 degrees, and the second inclination angle A2 of the side surface of the second opening volume O2 may be less than 90 degrees.

In the second opening volume O2, a width in a first direction DR1 (e.g., a horizontal direction) may decrease in the third direction DR3 (e.g., a vertical direction). As such, in an embodiment where the second opening volume O2 has a tapered shape, the shadow effect may be optimized to easily control the deposition thickness and deposition area and minimize deposition material loss.

Referring to FIG. 3, the first inclination angle A1 of the side surface of the first opening volume O1 may be 90 degrees. For example, in the first opening volume O1, a width in the first direction DR1 may be substantially constant along the third direction DR3.

Referring to FIG. 4, the first inclination angle A1 of the side surface of the first opening volume O1 may be greater than 90 degrees. For example, in the first opening volume O1, a width in the first direction DR1 may increase along the third direction DR3.

The second opening OP2 may penetrate a near or second surface SM2 of the deposition mask MSK. The second opening OP2 may overlap the first openings OP1 in the third direction DR3. The second opening OP2 may penetrate the second section IL22 of the second inorganic layer IL2, the second portion IL12 of the first inorganic layer IL1, and the base substrate BS in the third direction DR3. Accordingly, the deposition material may be provided to the main substrate MSB through the second opening OP2.

Hereinafter, a display device manufactured using the deposition mask MSK described with reference to FIGS. 2 to 4, and an electronic device including the same, will be described.

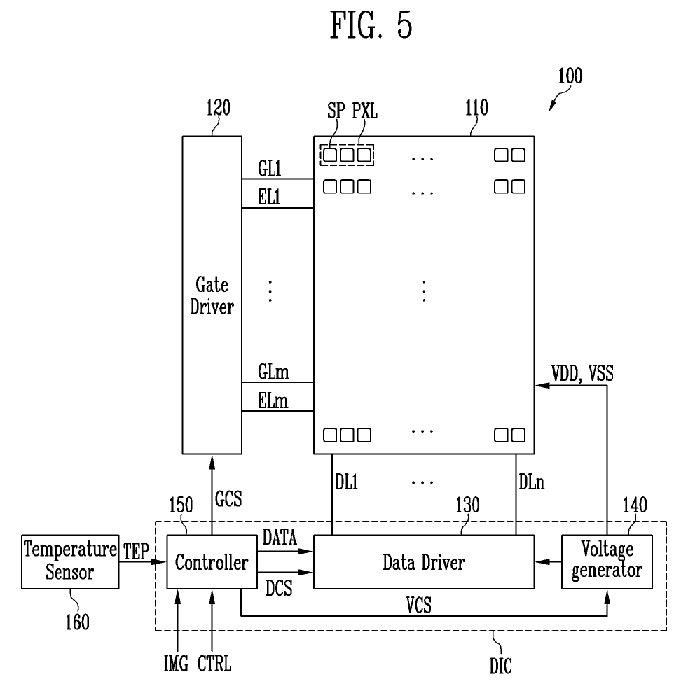

FIG. 5 illustrates an embodiment of a display device, indicated generally by the reference numeral 100.

The display device 100 of FIG. 5 may be manufactured using the deposition mask MSK as described above.

Referring to FIG. 5, the display device 100 may include a display panel 110, a gate driver 120, a data driver 130, a voltage generator 140, a voltage generator, and a controller 150.

The display panel 110 may include sub-pixels SP. The sub-pixels SP may be connected to the gate driver 120 via first to m-th gate lines GL1 to GLm, which may be arranged in a column direction and extend in a row direction. The sub-pixels SP may be connected to the data driver 130 via first to n-th data lines DL1 to DLn, which may be arranged in a row direction and extend in a column direction.

Each of the sub-pixels SP may include at least one light-emitting element configured to generate light. Accordingly, each of the sub-pixels SP may generate light of a particular color, such as red, green, blue, cyan, magenta, yellow, or the like. Two or more of the sub-pixels SP may form one pixel PXL. For example, as illustrated in FIG. 5, three sub-pixels SP may constitute a single pixel PXL.

The gate driver 120 may be coupled to the sub-pixels SP, which may be arranged in the row direction within each pixel PXL, via the first to m-th gate lines GL1 to GLm. The gate driver 120 may output gate signals to the first to m-th gate lines GL1 to GLm in response to a gate control signal GCS from the controller 150. In an embodiment, the gate control signal GCS may include a start signal to indicate a start of each frame, a horizontal synchronization signal to output gate signals in synchronization with a timing of data signals being applied, and the like.

In an embodiment, first to m-th light emission control lines EL1 to Elm, which may be arranged in a column direction and extend in a row direction, may be connected to sub-pixels SP. The gate driver 120 may include a light emission control driver configured to control the first to m-th light emission control lines EL1 to ELm, and the light emission control driver may operate under control of the controller 150.

The gate driver 120 may be located on one side of the display panel 110. However, embodiments are not necessarily limited thereto. For example, the gate driver 120 may be physically and/or logically separated into two or more drivers, and such drivers may be located on one side of the display panel 110 and on another side of the display panel 110, such as opposite to the one side. As such, the gate drivers 120 may be located around the periphery of the display panel 110 in various configurations according to embodiments.

The data driver 130 may be connected to the sub-pixels SP via first to n-th data lines DL1 to DLn arranged in the row direction and extending in the column direction. The data driver 130 may receive image data DATA and a data control signal DCS from the controller 150. The data driver 130 may operate in response to the data control signal DCS. In an embodiment, the data control signal DCS may include a source start pulse, a source shift clock, a source output enable signal, and the like.

Using voltages received from the voltage generator 140, the data driver 130 may apply data signals having grayscale voltages corresponding to the image data DATA to the first to n-th data lines DL1 to DLn. When a gate signal is applied to each of the first to m-th gate lines GL1 to GLm, data signals corresponding to the image data DATA may be applied to the data lines DL1 to DLn. Accordingly, the corresponding sub-pixels SP may generate light corresponding to the data signals, and the image may be displayed on the display panel 110.

In an embodiment, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate voltages and provide the generated voltages to components of the display device 100. For example, the voltage generator 140 may be configured to generate the voltages by receiving an input voltage from outside the display device 100, regulating the received voltage, and further regulating the regulated voltage.

The voltage generator 140 may generate a first power voltage VDD and a second power voltage VSS, and the first and second power voltages VDD and VSS may be provided to the sub-pixels SP. The first power voltage VDD may have a relatively high voltage level, and the second power voltage VSS may have a lower voltage level than the first power voltage VDD. In another embodiment, the first power voltage VDD or the second power voltage VSS may be provided by an external device to the display device 100.

In addition, the voltage generator 140 may generate various voltages. For example, the voltage generator 140 may generate an initialization voltage that is applied to the sub-pixels SP. For example, in a sensing operation for sensing electrical characteristics of transistors and/or light-emitting elements of the sub-pixels SP, a specific reference voltage may be applied to the first to n-th data lines DL1 to DLn, and the voltage generator 140 may generate such a reference voltage.

The controller 150 may control various operations of the display device 100. The controller 150 may receive, such as from an external source. input image data IMG and a control signal CTRL to control a display of the input image data IMG. In response to the control signal CTRL, the controller 150 may provide the gate control signal GCS, the data control signal DCS, and the voltage control signal VCS.

The controller 150 may convert the input image data IMG into a form suitable for the display device 100 or display panel 110 to output image data DATA. In an embodiment, the controller 150 may output the image data DATA by arranging the input image data IMG to be specifically suitable for the sub-pixels SP on a row-by-row basis.

Two or more components among the data driver 130, the voltage generator 140, and the controller 150 may be mounted on and/or integrated into a single integrated circuit. As shown in FIG. 5, the data driver 130, the voltage generator 140, and the controller 150 may be included in a driver integrated circuit DIC. In such an embodiment, the data driver 130, the voltage generator 140, and the controller 150 may be functionally distinct components within the single driver integrated circuit DIC. In another embodiment, at least one among the data driver 130, the voltage generator 140, and the controller 150 may be provided as a component separate from the driver integrated circuit DIC.

The display device 100 may further include at least one temperature sensor 160. The temperature sensor 160 may be configured to detect a temperature of its surroundings, and to generate temperature data TEP indicating the temperature detected. In an embodiment, the temperature sensor 160 may be placed adjacent to the display panel 110 and/or the driver integrated circuit DIC.

The controller 150 may control various operations of the display device 100 in response to the temperature data TEP. In an embodiment, the controller 150 may adjust brightness of an image output from the display panel 110 in response to temperature data TEP. For example, the controller 150 may adjust data signals and the first and second power voltages VDD and VSS by controlling components such as the data driver 130 and/or the voltage generator 140 to generate relatively less heat when the temperature data TEP indicates a relatively high temperature.

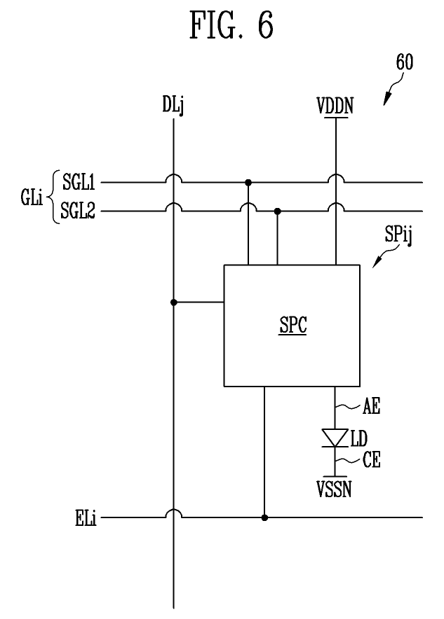

FIG. 6 illustrates an embodiment of any one of the sub-pixels of FIG. 5, indicated generally by the reference numeral 60. In FIG. 6, a sub-pixel SPij arranged in an i-th row (where i is a positive integer less than or equal to m) and a j-th column (where j is a positive integer less than or equal to n) among the sub-pixels SP of FIG. 5 may be illustrated by way of example.

Referring to FIG. 6, the sub-pixel SPij may include a sub-pixel circuit SPC and a light-emitting element LD.

The light-emitting element LD may be connected between a first power voltage node VDDN and a second power voltage node VSSN. The first power voltage node VDDN may be a node that delivers the first power voltage VDD of FIG. 5, and the second power voltage node VSSN may be a node that delivers the second power voltage VSS of FIG. 5.

An anode electrode AE of the light-emitting element LD may be connected to the first power voltage node VDDN via the sub-pixel circuit SPC, and a cathode electrode CE of the light-emitting element LD may be connected to the second power voltage node VSSN. For example, the anode electrode AE of the light-emitting element LD may be connected to the first power voltage node VDDN via one or more transistors included in the sub-pixel circuit SPC.

The sub-pixel circuit SPC may be connected to an i-th gate line GLi of the first to m-th gate lines GL1 to GLm of FIG. 5, an i-th emission control line ELi of the first to m-th emission control lines EL1 to ELm of FIG. 5, and a j-th data line DLj of the first to n-th data lines DL1 to DLn of FIG. 5. The sub-pixel circuit SPC may be configured to control the light-emitting element LD in response to signals received via these three signal lines.

The sub-pixel circuit SPC may operate in response to a gate signal received via the i-th gate line GLi. The i-th gate line GLi may include one or more sub-gate lines. In an embodiment, the i-th gate line GLi may include first and second sub-gate lines SGL1 and SGL2. The sub-pixel circuit SPC may operate in response to gate signals received via the first and second sub-gate lines SGL1 and SGL2. In an embodiment where the i-th gate line GLi includes two or more sub gate lines, the sub-pixel circuit SPC may operate in response to gate signals received through those sub-gate lines.

The sub-pixel circuit SPC may operate in response to an emission control signal received via the i-th emission control line ELi. In an embodiment, the i-th emission control line ELi may include one or more sub-emission control lines. In an embodiment where the first light emission control line ELi includes two or more sub-emission control lines, the sub-pixel circuit SPC may operate in response to emission control signals received through those sub-emission control lines.

The sub-pixel circuit SPC may receive a data signal via the j-th data line DLj. The sub-pixel circuit SPC may store a voltage corresponding to the data signal in response to at least one of the gate signals received via the first and second sub-gate lines SGL1 and SGL2. In response to the emission control signal received via the i-th emission control line ELi, the sub-pixel circuit SPC may control the current flowing from the first power voltage node VDDN to the second power voltage node VSSN through the light-emitting element LD according to the stored voltage. Accordingly, the light-emitting element LD may generate light of a luminance corresponding to the data signal.

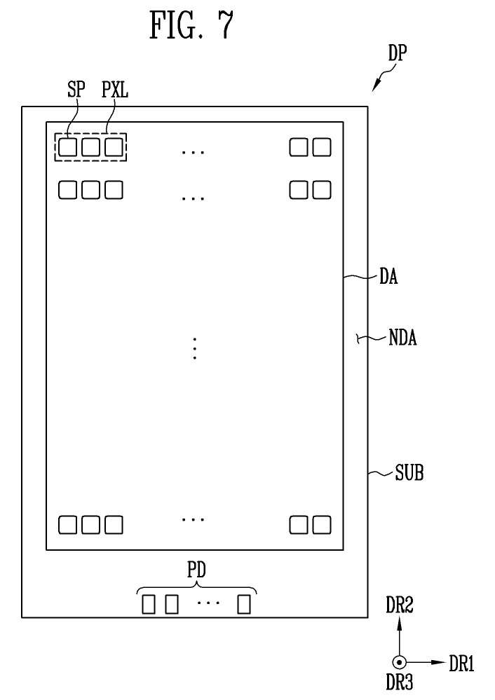

FIG. 7 illustrates an embodiment of the display panel of FIG. 5, indicated generally by the reference indicator DP.

Referring to FIG. 7, the embodiment DP of the display panel 110 of FIG. 5 may include a display area DA and a non-display area NDA. The display panel DP may display an image through the display area DA. The non-display area NDA may be located around an edge of the display area DA.

The display panel DP may include a substrate SUB, a plurality of pixels PXL each having sub-pixels SP, and pads PD.

In case of an embodiment where the display panel DP is to be used as a display screen for a Head Mounted Display (HMD), a Virtual Reality (VR) device, a Mixed Reality (MR) device, an Augmented Reality (AR) device, or the like, the display panel DP may be located very close to the user’s eyes and sub-pixels SP of relatively high integration may be appropriate. To increase the integration of the sub-pixels SP, the substrate SUB may be provided as a silicon substrate. Upon such a silicon substrate SUB, the sub-pixels SP and/or the display panel DP may be formed. The silicon substrate SUB may correspond to an embodiment of the main substrate MSB of FIG. 1. The display device 100 including the display panel DP formed on the silicon substrate SUB, may be referred to as an OLED on Silicon (OLEDoS) display device.

The sub-pixels SP may be located in the display area DA on the substrate SUB. The sub-pixels SP may be arranged in a matrix form along a first direction DR1 and a second direction DR2 intersecting the first direction DR1. However, embodiments are not necessarily limited thereto. For example, the sub-pixels SP may be arranged in a zigzag shape along the first direction DR1 and the second direction DR2. For example, the sub-pixels SP may be arranged in a PENTILE^{TM} form. The first direction DR1 may be a row direction, and the second direction DR2 may be a column direction. Two or more sub-pixels of the sub-pixels SP may constitute one pixel PXL.

In the non-display area NDA on the substrate SUB, components for controlling the sub-pixels SP may be located. For example, wiring associated with the sub pixels SP, such as the first to m-th gate lines GL1 to GLm and the first to n-th data lines DL1 to DLn of FIG. 5, may be arranged in the non-display area NDA.

At least one among the gate driver 120, the data driver 130, the voltage generator 140, the controller 150, and the temperature sensor 160 of FIG. 5 may be mounted on and/or integrated into the non-display area NDA of the display panel DP. In an embodiment, the gate driver 120 of FIG. 5 may be mounted on the display panel DP and located in the non-display area NDA. In another embodiment, the gate driver 120 may be implemented as an integrated circuit separate from the display panel DP. In an embodiment, the temperature sensor 160 may be placed in the non-display area NDA to detect a temperature of the display panel DP.

The pads PD may be located on the substrate SUB in the non-display area NDA. The pads PD may be electrically connected to the sub-pixels SP through wirings. For example, the pads PD may be connected to the sub-pixels SP via first to n-th data lines DL1 to DLn.

The pads PD may interface the display panel DP to other components of the display device 100. In an embodiment, voltages and signals appropriate for operation of the components included in the display panel DP may be provided from a driver integrated circuit DIC of FIG. 5 through the pads PD. For example, the first to n-th data lines DL1 to DLn may be connected to the driver integrated circuit DIC via the pads PD. For example, the first and second power voltages VDD and VSS may be received from the driver integrated circuit DIC via the pads PD. For example, in an embodiment where the gate driver 120 is mounted on the display panel DP, a gate control signal GCS may be transmitted from the driver integrated circuit DIC via the pads PD to the gate driver 120.

In an embodiment, a circuit board may be electrically connected to the pads PD using a conductive adhesive or member such as an anisotropic conductive film. In such an embodiment, the circuit board may be a flexible circuit board or a flexible film having a flexible material. The driver integrated circuit DIC may be mounted on the circuit board and electrically connected to the pads PD.

In an embodiment, the display area DA may have various shapes. The display area DA may have the shape of a closed loop including straight and/or curved sides. For example, the display area DA may have shapes such as a polygon, a circle, a semicircle, an ellipse, or the like.

In an embodiment, the display panel DP may have a flat display surface. In another embodiment, the display panel DP may have an at least partially rounded display surface. In an embodiment, the display panel DP may be bendable, foldable, and/or rollable. In such an embodiment, the display panel DP and/or the substrate SUB may include materials having a relatively flexible property.

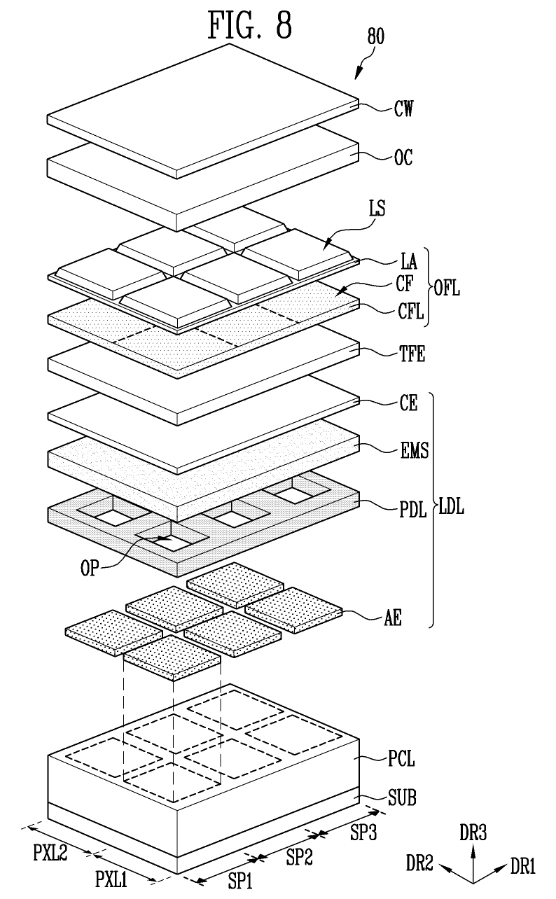

FIG. 8 illustrates an embodiment of a portion of the display panel of FIG. 7, indicated generally by the reference numeral 80.

Referring to FIGS. 7 and 8, each of the first and second pixels PXL1 and PXL2 may include first to third sub-pixels SP1 to SP3. However, embodiments are not necessarily limited thereto. For example, each of the first and second pixels PXL1 and PXL2 may include four sub-pixels, or may include two sub-pixels.

In FIG. 8, the first to third sub-pixels SP1 to SP3 may be illustrated to have rectangular shapes and substantially the same size when viewed in a third direction DR3 intersecting with the first and second directions DR1 and DR2. However, embodiments are not necessarily limited thereto. For example, the first to third sub-pixels SP1 to SP3 may be modified to have different shapes, sizes and/or arrangements in a plan view.

The display panel DP may include a substrate SUB, a pixel circuit layer PCL, a light-emitting element layer LDL, an encapsulation layer TFE, an optical functional layer OFL, an overcoat layer OC, and a cover window CW.

In an embodiment, the substrate SUB may include a silicon wafer substrate formed through a semiconductor process. The substrate SUB may include semiconductor material suitable for forming circuit elements. For example, the semiconductor material may include silicon, germanium, and/or silicon-germanium. The substrate SUB may be provided from a bulk wafer, an epitaxial layer, a silicon on insulator (SOI) layer, a semiconductor on insulator (SeOI) layer, or the like. In another embodiment, the substrate SUB may include a glass substrate. In another embodiment, the substrate SUB may include a polyimide (PI) substrate.

The pixel circuit layer PCL may be disposed on the substrate SUB. The substrate SUB and/or the pixel circuit layer PCL may include insulating layers, and may further include conductive patterns disposed between the insulating layers. The conductive patterns of the pixel circuit layer PCL may function as at least portions of the circuit components, lines, or the like. The conductive patterns may include copper, but embodiments are not necessarily limited thereto.

The circuit elements may include respective sub-pixel circuits SPC, such as shown in FIG. 6, for each of the first to third sub-pixels SP1 to SP3. Each sub-pixel circuit SPC may include transistors and one or more capacitors. Each transistor may include a semiconductor portion including a source area, a drain area, and a channel area, and a gate electrode overlapping the semiconductor portion in at least one direction. In an embodiment where the substrate SUB is formed of a silicon substrate, the semiconductor portion may be included in the substrate SUB, and the gate electrode may be included in the pixel circuit layer PCL as a conductive pattern of the pixel circuit layer PCL. In an embodiment where the substrate SUB is formed of a glass substrate or a PI substrate, the semiconductor portion and the gate electrode may be included in the pixel circuit layer PCL.

Each capacitor may include electrodes such as an anode and a cathode spaced apart from each other. For example, each capacitor may include electrodes spaced apart from each other on a plane defined in the first and second directions DR1 and DR2. For example, each capacitor may include electrodes spaced apart from each other in the third direction DR3 with an insulating layer interposed therebetween.

The lines of the pixel circuit layer PCL may include signal lines connected to each of the first to third sub-pixels SP1 to SP3. For example, the signal lines may include a gate line, an emission control line, and a data line. The lines may further include a line connected to the first power voltage node VDDN of FIG. 6. The lines may further include a line connected to the second power voltage node VSSN of FIG. 6.

The light-emitting element layer LDL may include anode electrodes AE, a pixel defining layer PDL, a light-emitting structure EMS, and a cathode electrode CE.

The anode electrodes AE may be disposed on the pixel circuit layer PCL. The anode electrodes AE may be electrically connected to circuit elements of the pixel circuit layer PCL. The anode electrodes AE may include an opaque conductive material capable of reflecting light, but embodiments are not necessarily limited thereto.

The pixel defining layer PDL may be disposed on the anode electrodes AE. The pixel defining layer PDL may include openings OP that each exposes a portion of each of the anode electrodes AE, respectively. The openings OP of the pixel defining layer PDL may each be understood as an emission area corresponding to the first to third sub-pixels SP1 to SP3, respectively.

In an embodiment, the pixel defining layer PDL may include inorganic material. In such an embodiment, the pixel defining layer PDL may include a plurality of inorganic layers stacked on top of one another. For example, the pixel defining layer PDL may include silicon oxide (SiOx) and silicon nitride (SiNx). In another embodiment, the pixel defining layer PDL may include organic material. However, the material of the pixel defining layer PDL is not necessarily limited to the aforementioned examples.

The light-emitting structure EMS may be disposed on the anode electrodes AE exposed through the openings OP in the pixel defining layer PDL. In such an embodiment, the first openings OP1 of the deposition mask MSK may expose the opening OP of the pixel defining layer PDL, and the light-emitting structure EMS may be deposited on the opening OP of the pixel defining layer PDL using the deposition mask MSK. The light-emitting structure EMS may include a light-emitting layer configured to generate light, an electron transport layer configured to transport electrons, and a hole transport layer configured to transport holes. In an embodiment, portions of the light-emitting structure EMS corresponding to the first to third sub-pixels SP1 to SP3 may be separated from each other, and each separated light-emitting structure EMS may be disposed in a corresponding opening OP of the pixel defining layer PDL.

The cathode electrode CE may be disposed on the light-emitting structure EMS. The cathode electrode CE may extend across the first to third sub-pixels SP1 to SP3. As such, the cathode electrode CE may be provided as a common electrode for the first to third sub-pixels SP1 to SP3.

The cathode electrode CE may be a thin-film metal layer having a thickness allowing light emitted from the light-emitting structure EMS to pass therethrough. The cathode electrode CE may be made of a metal material having a relatively small thickness, or a transparent conductive material. In an embodiment, the cathode electrode CE may include at least one of various transparent conductive materials including indium tin oxide, indium zinc oxide, indium tin zinc oxide, aluminum zinc oxide, gallium zinc oxide, zinc tin oxide, or gallium tin oxide. In another embodiment, the cathode electrode CE may include at least one of silver (Ag), magnesium (Mg), and a compound thereof. However, the material of the cathode electrode CE is not necessarily limited to the aforementioned example.

Any one of the anode electrodes AE, a portion of the light-emitting structure EMS that overlap the any one anode electrode AE, and a portion of the cathode electrode CE that overlaps the portion of the light-emitting structure EMS can be understood as constituting one light-emitting element LD (refer to FIG. 6). In other words, each of the light-emitting elements of the first to third sub-pixels SP1 to SP3 may include one anode electrode, a portion of the light-emitting structure EMS that overlaps the one anode electrode AE, and a portion of the cathode electrode CE that overlaps the portion of the light-emitting structure. In each of the first to third sub-pixels SP1 to SP3, free electrons injected from the cathode electrode CE and holes, or the absence of bound electrons, injected from the anode electrode AE, are transported into the light-emitting layer of the light-emitting structure EMS, thus forming excitons. When the excitons make a transition from an excited state to a bound state, light can be generated. Depending on the amount of current flowing through the light-emitting layer, the luminance of light may be varied. Depending on the configuration of the light-emitting layer, the wavelength range of light to be generated may be determined.

The encapsulation layer TFE may be disposed on the cathode electrode CE. The encapsulation layer TFE may cover the light-emitting element layer LDL and/or the pixel circuit layer PCL. The encapsulation layer TFE may be configured to prevent oxygen and/or water or the like from penetrating into the light-emitting element layer LDL. In an embodiment, the encapsulation layer TFE may include a structure formed by alternately stacking one or more inorganic layers and one or more organic layers. For example, the inorganic layer may include silicon nitride (SiNx), silicon oxide (SiOx), silicon oxynitride (SiOxNy), or the like. For example, the organic layer may include organic insulating material such as acrylic resin, epoxy resin, phenol resin, polyamide resin, polyimide resin, unsaturated polyester resin, polyphenylene ether resin, polyphenylene sulfide resin, or benzocyclobutene (BCB). However, the materials of the organic layer and the inorganic layer of the encapsulation layer TFE are not necessarily limited to the aforementioned examples.

The optical functional layer OFL may be disposed on the encapsulation layer TFE. The optical functional layer OFL may include a color filter layer CFL and a lens layer LA.

The color filter layer CFL may be disposed between the encapsulation layer TFE and the lens layer LA. The color filter layer CFL may be configured to filter light emitted from the light-emitting structure EMS and selectively output light in a wavelength range or color corresponding to each sub-pixel. The color filter layer CFL may include color filters CF respectively corresponding to the first to third sub-pixels SP1 to SP3. Each of the color filters CF permits light within a wavelength range corresponding to the related sub-pixel to pass therethrough. For example, the color filter that corresponds to the first sub-pixel SP1 may permit light in a red color to pass therethrough, the color filter that corresponds to the second sub-pixel SP2 may permit light in a green color to pass therethrough, and the color filter that corresponds to the third sub-pixel SP3 may permit light in a blue color to pass therethrough. Depending on the wavelengths of light originally emitted from the light-emitting structure EMS of each sub-pixel, at least some of the color filters CF may be omitted.

The lens layer LA may be disposed on the color filter layer CFL. The lens layer LA may include lenses LS that respectively correspond to the first to third sub-pixels SP1 to SP3. Each of the lenses LS may pass and direct light emitted from the light-emitting structure EMS along an intended path, thus enhancing the light output efficiency. The lens layer LA may have a relatively high refractive index. For example, the lens layer LA may have a higher refractive index than the overcoat layer OC. In an embodiment, the lenses LS may include organic material. In an embodiment, the lenses LS may include acrylic material. However, the material of the lenses LS is not necessarily limited to the aforementioned example.

In an embodiment, compared to the opening OP of the pixel defining layer PDL, at least some of the color filters CF of the color filter layer CFL and at least some of the lenses LS of the lens layer LA may be shifted in a direction parallel to the plane defined in the first and second directions DR1 and DR2. For example, in a central area of the display area DA, the center of each color filter and the center of each lens may be aligned or overlapped with the center of the corresponding opening OP of the pixel defining layer PDL. For example, in the central area of the display area DA, the opening OP of the pixel defining layer PDL may completely overlap the corresponding color filter of the color filter layer CFL and the corresponding lens of the lens layer LA. In an area adjacent to the non-display area NDA within the display area DA, the center of the color filter and the center of the lens may be shifted in a planar direction from the center of the corresponding opening OP of the pixel defining layer PDL when viewed in the third direction DR3. For example, in the area adjacent to the non-display area NDA within the display area DA, each opening OP of the pixel defining layer PDL may partially overlap the corresponding color filter of the color filter layer CFL and the corresponding lens LS of the lens layer LA. For example, in the area adjacent to the non-display area NDA within the display area DA, each color filter of the color filter layer CFL and the corresponding lens LS of the lens layer LA may be progressively shifted towards the central area of the display area DA relative to the corresponding opening OP of the pixel defining layer PDL for subpixels correspondingly closer to the non-display area, and axes of the openings OP may be progressively inclined to align with the progressively shifted color filter and lens, respectively. Accordingly, light emitted from the light-emitting structure EMS in the central portion of the display area DA may be efficiently outputted in the normal direction of the display surface. Light emitted from the light-emitting structure EMS around the perimeter of the display area DA may be efficiently outputted in a direction inclined at a certain angle with respect to the normal direction of the display surface.

The overcoat layer OC may be disposed on the lens layer LA. The overcoat layer OC may cover the optical functional layer OFL, the encapsulation layer TFE, the light-emitting structure EMS, and/or the pixel circuit layer PCL. The overcoat layer OC may include various materials suitable for protecting underlying layers from foreign substances such as dust, water, or the like. For example, the overcoat layer OC may include at least one of an inorganic insulating layer and an organic insulating layer. For instance, the overcoat layer OC may include epoxy, but embodiments are not necessarily limited thereto. The overcoat layer OC may have a lower refractive index than the lens layer LA.

The cover window CW may be disposed on the overcoat layer OC. The cover window CW may be configured to protect underlying layers. The cover window CW may have a higher refractive index than the overcoat layer OC. The cover window CW may include glass, but embodiments are not necessarily limited thereto. For example, the cover window CW may be an encapsulation glass layer configured to protect components disposed thereunder. In another embodiment, the cover window CW may be omitted.

The display device 100 according to an embodiment may be applied to various electronic devices. For example, the electronic device according to an embodiment may include the display device 100 described above, and may include more modules or devices having other additional functions in addition to the display device.

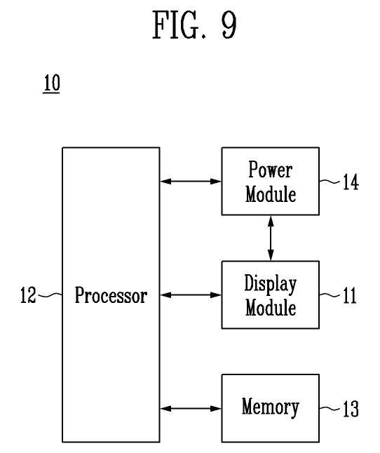

FIG. 9 illustrates an electronic device according to an embodiment, indicated generally by the reference numeral 10.

Referring to FIG. 9, the electronic device 10 may include a display module 11, a processor 12, a memory 13, and a power module 14.

The processor 12 may include at least one of a central processing unit (CPU), an application processor (AP), a graphics processing unit (GPU), a communications processor (CP), an image signal processor (ISP), and/or a controller.

The memory 13 may store data information for the operation of the processor 12 or the display module 11. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter, a battery device, a solar cell, or the like, and a power conversion module that converts power supplied by the power supply module to generate power suitable for operation of the electronic device 10.

At least one of the above-described components of the electronic device 10 may be included in the display device 100 according to the above-described embodiments. In addition, some parts of individual modules functionally included in one module may be included in the display device 100, and other parts may be provided separately from the display device 100. For example, the display device 100 may include the display module 11, while the processor 12, the memory 13, and the power module 14 may be provided in the form of devices other than the display device 100 in the electronic device 10.

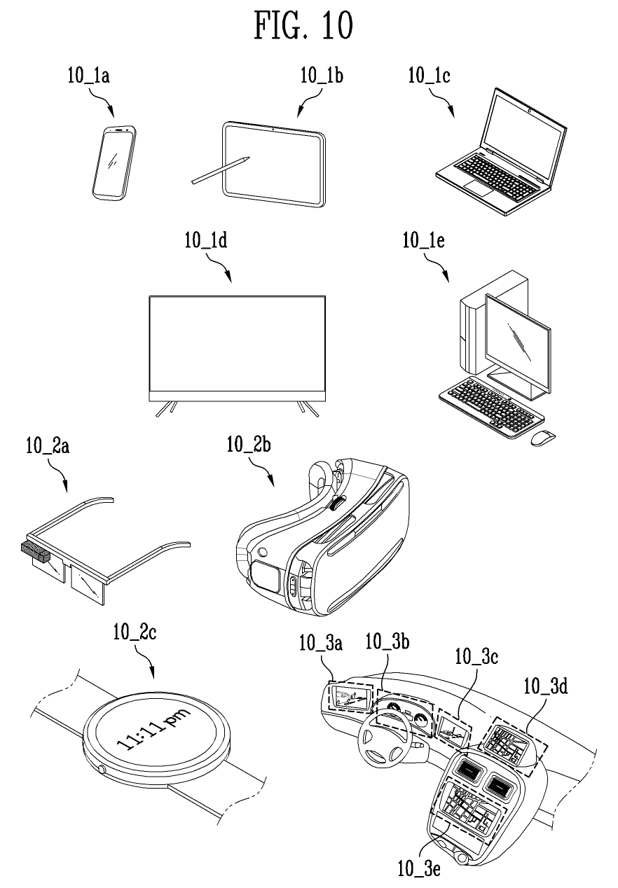

FIG. 10 illustrates various configurations of an electronic device according to an embodiment, indicated generally by the reference indicia 10_1a-10_1e, 10_2a-10_2c, and 10_3a-10_3e.

Referring to FIG. 10, various configurations of the electronic device 10 to which a display device 100 according to embodiments is applied may include not only an electronic device for displaying an image such as a smartphone 10_1a, a tablet PC 10_1b, a laptop 10_1c, a TV 10_1d, and a computer monitor 10_1e, but also a wearable electronic device including a display module such as smart glasses 10_2a, a head mounted display 10_2b, and a smart watch 10_2c, and automotive electronic devices each including a display module, such as a CID (Center Information Display) disposed relative to an instrument panel to the left 10_3a, on 10_3b, and/or to the right 10_3c thereof, on a center console or fascia 10_3e, on a dashboard 10_3d of a vehicle, a room mirror display, and/or the like.

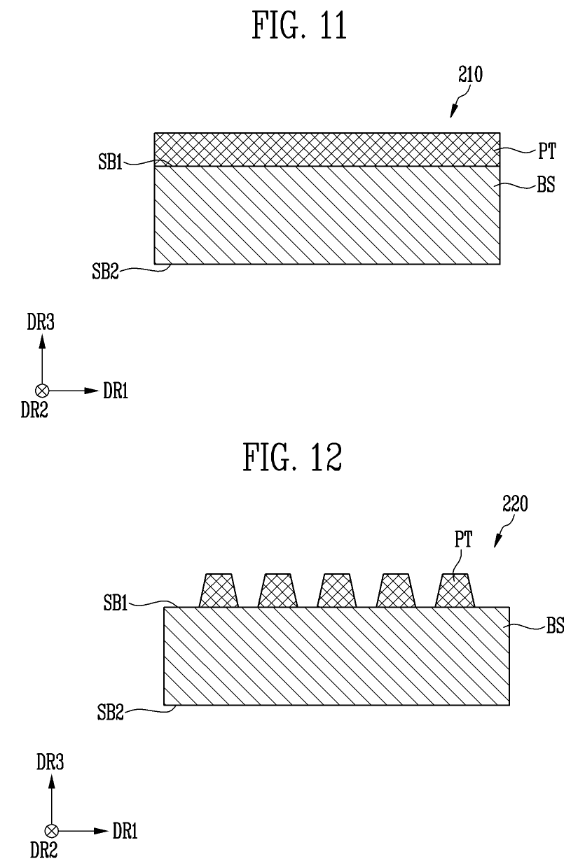

FIGS. 11 to 17 illustrate manufacturing stages at process steps of a method for manufacturing a deposition mask, such as the deposition mask of FIG. 2, according to an embodiment. The product stages may be shown in simplified form for illustrative purposes such that more detailed symbols may be omitted.

Referring to FIG. 11, at a manufacturing stage indicated generally by the reference numeral 210, the method may prepare a base substrate BS having a first surface SB1 and an opposite second surface SB2, and form a pattern layer PT on the first surface SB1 of the base substrate BS. The pattern layer PT may include metals with a melting point of 850℃ or higher. For example, the pattern layer PT may include chromium (Cr), tungsten (W), molybdenum (Mo), and titanium nitride (TiN), but is not necessarily limited thereto. According to an embodiment, the pattern layer PT may further include an amorphous carbon layer.

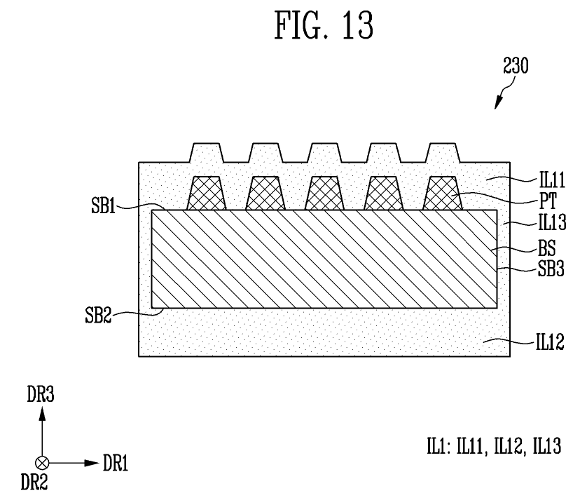

Referring to FIG. 12, at a manufacturing stage indicated generally by the reference numeral 220, the method may then pattern the pattern layer PT. Patterned protrusions of the pattern layer PT may decrease in width in the first direction DR1 as they extend in the third direction DR3.

Referring to FIG. 13, at a manufacturing stage indicated generally by the reference numeral 230, the method may then form a first inorganic layer IL1 on the pattern layer PT. A first section IL11 of the first inorganic layer IL1 may be formed on a first surface SB1 and the pattern layer PT of the base substrate BS. The first section IL11 may include a portion that protrudes in the third direction DR3 based on a shape of the pattern layer PT. A second section IL12 of the first inorganic layer IL1 may be formed on the second surface SB2 of the base substrate BS. A third section IL13 of the first inorganic layer IL1 may be formed on a side or third surface SB3 of the base substrate BS. The first inorganic layer IL1 may be formed of silicon nitride (SiNx), but is not necessarily limited thereto.

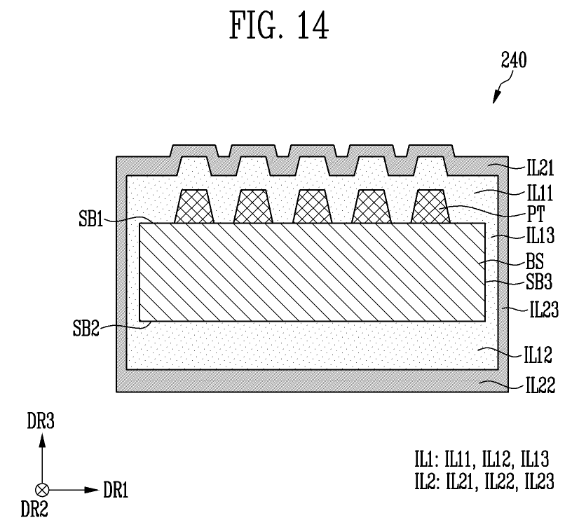

Referring to FIG. 14, at a manufacturing stage indicated generally by the reference numeral 240, the method may then form a second inorganic layer IL2 on the first inorganic layer IL1. A first section IL21 of the second inorganic layer IL2 may be formed on the first section IL11 of the first inorganic layer IL1. The first section IL21 of the second inorganic layer IL2 may include a portion that protrudes in the third direction DR3 based on a shape of the first section IL11 of the first inorganic layer IL1. A second section IL22 of the second inorganic layer IL2 may be formed on the second section IL12 of the first inorganic layer IL1. A third section IL23 of the second inorganic layer IL2 may be formed on the third section IL13 of the first inorganic layer IL1. The second inorganic layer IL2 may be formed of silicon oxide (SiOx), but is not necessarily limited thereto.

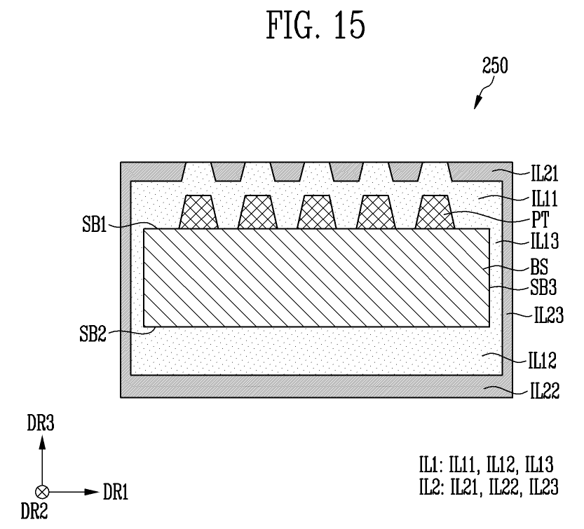

Referring to FIG. 15, at a manufacturing stage indicated generally by the reference numeral 250, the method may then polish an upper surface of the inorganic layers IL1 and IL2. For example, the upper surface of the inorganic layers IL1 and IL2 may be flattened through Chemical Mechanical Polishing (CMP).

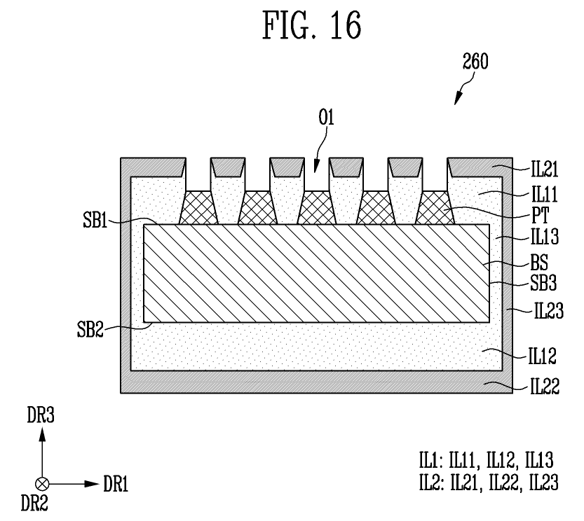

Referring to FIG. 16, at a manufacturing stage indicated generally by the reference numeral 260, the method may then etch the inorganic layers IL1 and IL2 on the pattern layer PT to form the first opening volumes O1. For example, the first section IL11 of the first inorganic layer IL1 may be etched to form the first opening volumes O1. The first opening volumes O1 may each expose an upper surface of the pattern layer PT.

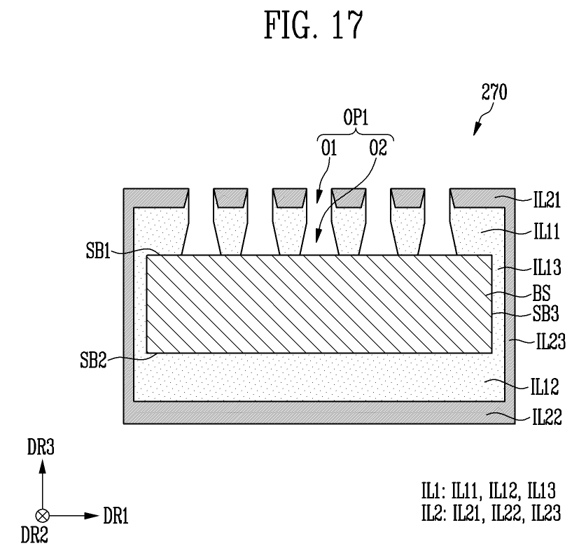

Referring to FIG. 17, at a manufacturing stage indicated generally by the reference numeral 270, the method may then etch or remove the remaining pattern layer PT to form the second opening volumes O2. The pattern layer PT may be etched through the first opening volumes O1. The second opening volumes O2 may each expose the first surface SB1 of the base substrate BS.

The second opening volumes O2 may have substantially the same shape as the previous stage’s pattern layer PT. For example, the second opening volumes O2 may each decrease in width in the first direction DR1 as they extend in the third direction DR3. Where the second opening volumes O2 have a tapered shape, it is possible to optimize the shadow effect to easily control the deposition thickness and deposition area and minimize deposition material loss, as explained above.

The second section IL22 of the second inorganic layer IL2, the second section IL12 of the first inorganic layer, and the base substrate BS may then be sequentially etched to form the second opening OP2 to complete the deposition mask MSK of FIG. 2.

Although illustrative embodiments have been shown and described by way of example, those of ordinary skill in the pertinent art may readily appreciate that other variants may be derived from the above description. Therefore, the scope and spirit of present disclosure is not necessarily limited to these embodiments, but is defined only by the claims set forth below, including variants and equivalents thereof.

What is claimed is:

1. A deposition mask comprising:
first openings penetrating a first surface; and
a second opening penetrating a second surface and overlapping the first openings,
wherein each of the first openings includes a first opening volume and a second opening volume contiguous with the first opening volume and disposed between the first opening volume and the second opening,
wherein a first inclination angle of a side surface of the first opening volume is different from a second inclination angle of a side surface of the second opening volume.

2. The deposition mask of claim 1, further comprising:
a base substrate; and
an inorganic layer including a first portion on a first surface of the base substrate and a second portion on a second surface of the base substrate.

3. The deposition mask of claim 2, wherein the first openings penetrate the first portion of the inorganic layer.

4. The deposition mask of claim 2, wherein the second opening penetrates the base substrate and the second portion of the inorganic layer.

5. The deposition mask of claim 2, wherein the inorganic layer includes a first inorganic layer on the base substrate and a second inorganic layer on the first inorganic layer.

6. The deposition mask of claim 1, wherein the first inclination angle is greater than the second inclination angle.

7. The deposition mask of claim 1, wherein a horizontal width of the first opening volume increases in a vertical direction.

8. The deposition mask of claim 1, wherein a horizontal width of the first opening volume is constant.

9. The deposition mask of claim 1, wherein a horizontal width of the second opening volume decreases in a vertical direction.

10. A method for manufacturing a deposition mask comprising:
forming a pattern layer on a first surface of a base substrate;
forming an inorganic layer on the pattern layer;
forming a plurality of first opening volumes, each having a side surface with a first inclination angle, by etching the inorganic layer on the pattern layer;
forming a plurality of second opening volumes, each contiguous with a respective first opening volume and having a side surface with a second inclination angle, by etching the pattern layer; and
forming a second opening by etching the inorganic layer and the base substrate,
wherein the first inclination angle is different from the second inclination angle.

11. The method for manufacturing a deposition mask of claim 10, wherein a horizontal width of the pattern layer decreases in a vertical direction.

12. The method for manufacturing a deposition mask of claim 10, further comprising:
polishing an upper surface of the inorganic layer.

13. The method for manufacturing a deposition mask of claim 10, wherein the plurality of first opening volumes expose an upper surface of the pattern layer.

14. The method for manufacturing a deposition mask of claim 10, wherein the pattern layer is etched through the plurality of first opening volumes.

15. The method for manufacturing a deposition mask of claim 14, wherein the plurality of second opening volumes expose the first surface of the base substrate.

16. The method for manufacturing a deposition mask of claim 10, wherein the inorganic layer includes a first portion formed on the first surface of the base substrate and a second portion formed on the second surface of the base substrate.

17. The method for manufacturing a deposition mask of claim 16, wherein the plurality of first opening volumes are formed by etching the first portion of the inorganic layer.

18. The method for manufacturing a deposition mask of claim 16, wherein the second opening is formed by etching the second portion of the inorganic layer and the base substrate.

19. The method for manufacturing a deposition mask of claim 10, wherein forming the inorganic layer includes:
forming a first inorganic layer on the pattern layer; and
forming a second inorganic layer on the first inorganic layer.

20. An electronic device comprising:
a display device manufactured using a deposition mask comprising:
first openings penetrating a first surface; and
a second opening penetrating a second surface and overlapping the first openings,
wherein each of the first openings includes a first opening volume and a second opening volume contiguous with the first opening volume and disposed between the first opening volume and the second opening,
wherein a first inclination angle of a side surface of the first opening volume is different from a second inclination angle of a side surface of the second opening volume.
